(19) United States
(12) Patent Application Publication
(10) Pub. No.: US 2011/0133187 A1
(43) Pub. Date: Jun. 9, 2011

(54) PHOTO DETECTOR AND METHOD OF MANUFACTURING THE SAME

(75) Inventors: Sang Hoon KIM, Seoul (KR); Gyungock Kim, Seoul (KR); In Gyoo Kim, Daejeon (KR); Dongwoo Suh, Daejeon (KR); Jiho Joo, Goyang (KR); Ki Seok Jang, Daejeon (KR)

(73) Assignee: Electronics and Telecommunications Research Institute, Daejeon (KR)

(21) Appl. No.: 12/765,705

(22) Filed: Apr. 22, 2010

(30) Foreign Application Priority Data
Dec. 3, 2009 (KR) 10-2009-0119308

(51) Int. Cl. H01L 31/0256; H01L 31/18; H01L 31/0232

(52) U.S. Cl. 257/51; 438/69; 438/97; 257/432; 257/E31.003; 257/E31.127

(57) ABSTRACT

Provided is a manufacturing method of a photo detector. The method includes: forming a first single crystal semiconductor layer and an optical waveguide protruding from the first single crystal semiconductor layer; forming an insulation layer on the first single crystal semiconductor layer to cover the optical waveguide; forming an opening by etching the insulation layer to expose the top surface of the optical waveguide; forming a second single crystal semiconductor layer from the top surface of the exposed optical waveguide, in the opening; and selectively forming a poly semiconductor layer from the top surface of the second single crystal semiconductor layer, the poly semiconductor layer being doped with dopants.

### CROSS-REFERENCE TO RELATED APPLICATIONS

This U.S. non-provisional patent application claims priority under 35 U.S.C. §119 of Korean Patent Application No. 10-2009-0119308, filed on Dec. 3, 2009, the entire contents of which are hereby incorporated by reference.

### BACKGROUND

The present invention disclosed herein relates to a photo detector and a method of manufacturing the same, and more particularly, to a photo detector including a waveguide and a method of manufacturing the same.

A light receiving device that converts a non electrical signal (e.g., light) into an electrical signal may be applied to various technical fields. The light receiving device's utilization becomes gradually greater in a semiconductor field recently in addition to an optical communication field that uses light as medium of information and an image sensor that converts light from an object into an electrical signal. According to this trend, a great effort is being continuously made to apply the light receiving device to various devices.

### SUMMARY

The present invention provides a photo detector having minimized defects and a method of manufacturing the same.

The present invention also provides a photo detector having improved manufacturing efficiency and a method of manufacturing the same.

Embodiments of the present invention provide manufacturing methods of a photo detector including: forming a first single crystal semiconductor layer and an optical waveguide protruding from the first single crystal semiconductor layer; forming an insulation layer on the first single crystal semiconductor layer to cover the optical waveguide; forming an opening by etching the insulation layer to expose the top surface of the optical waveguide; forming a second single crystal semiconductor layer from the top surface of the exposed optical waveguide, in the opening; and selectively forming a poly semiconductor layer from the top surface of the second single crystal semiconductor layer, the poly semiconductor layer being doped with dopants.

In some embodiments, the forming of the second single crystal semiconductor layer and the forming of the poly semiconductor layer may be successively performed in the same reaction chamber.

In other embodiments, the methods may further include doping the first single crystal semiconductor layer with dopants of a first conductive type, wherein the doping of the dopants of the first conductive type is performed before the forming of the second single crystal semiconductor layer.

In still other embodiments, the poly semiconductor layer may be doped with dopants of a second conductive type opposite to the first conductive type; and the dopants of the second conductive type may be doped in the poly semiconductor layer by an in-situ process.

In even other embodiments, the first single crystal semiconductor layer may include single crystal silicon and the second single crystal semiconductor layer includes single crystal germanium or single crystal silicon-germanium.

In yet other embodiments, the forming of the first single crystal semiconductor layer may include performing a dry etching process on a silicon layer of a Silicon On Insulator (SOI) substrate.

In further embodiments, the second single crystal semiconductor layer and the poly semiconductor layer may be formed through Reduced Pressure Chemical Vapor Deposition (RPCVD) or Ultra-High Vacuum Chemical Vapor Deposition (UHVCVD).

In still further embodiments, the forming of the second single crystal semiconductor layer may include a first step performed at a first temperature and a second step performed at a second temperature after the first step is performed, the second temperature being different from the first temperature. In one embodiment, the second temperature is higher than the first temperature.

In even further embodiments, the first step may include providing GeH₄ gas under a temperature of about 300° C. to about 500° C. and a pressure of about 30 Ton to about 80 Torr; and the second step may include providing GeH₄ gas under a temperature of about 600° C. to about 700° C. and a pressure of about 30 Torr to about 80 Torr.

In yet further embodiments, the forming of the poly semiconductor layer may include providing at least one of SiH₄ and GeH₄ and a carrier gas and may be performed under a temperature of about 650° C. to about 750° C. and a pressure of about 30 Torr to about 80 Torr.

In yet further embodiments, the forming of the poly semiconductor layer may further include providing HCI gas.

In yet further embodiments, the opening may have a width that is identical to or narrower than the width of the optical waveguide.

In yet further embodiments, the forming of the opening may include performing a dry etching process.

In other embodiments of the present invention, photo detectors include: a substrate; a buried oxide layer and a first single crystal semiconductor layer stacked on the substrate sequentially; an optical waveguide protruding from the first single crystal semiconductor layer; a second single crystal semiconductor layer having a sidewall that is self-aligned with a sidewall of the optical waveguide; and a poly semiconductor layer having a sidewall that is self-aligned with the sidewalls of the optical waveguide and the second single crystal semiconductor layer, wherein the optical waveguide includes a portion protruding from the first single crystal semiconductor layer and the top surface of the second single crystal semiconductor layer is non-planarized.

In some embodiments, the top surface of the poly semiconductor layer may have the same profile as the second single crystal semiconductor layer.

In other embodiments, the photo detectors may further include: a first interlayer insulation layer on the first single crystal semiconductor layer to surround the sidewalls of the optical waveguide, wherein the edge of the top surface of the optical waveguide is disposed lower than the top surface of the first interlayer insulation layer.

In still other embodiments, the top surface of the poly semiconductor layer may be disposed higher than the top surface of the first interlayer insulation layer.

In even other embodiments, the photo detectors may further include: a second interlayer insulation layer on the first interlayer insulation layer; a first electrode contact connected to the poly semiconductor layer electrically and penetrating the second interlayer insulation layer; and a second electrode contact connected to the first single crystal semiconductor layer electrically and penetrating the first interlayer insulation layer and the second interlayer insulation layer.

In yet other embodiments, the photo detector may further include a silicide layer between the poly semiconductor layer and the second electrode contact, wherein the poly semiconductor layer includes poly silicon.

In further embodiments, the first single crystal semiconductor layer may be doped with dopants of a first conductive type; the poly semiconductor layer may be doped with dopants of a second conductive type opposite to the first conductive type; and the second single crystal semiconductor layer may not be doped with dopants.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1 through 4 are manufacturing sectional views illustrating embodiments of the present invention; and

FIG. 5 is a flowchart illustrating a manufacturing method according to embodiments of the present invention.

### DETAILED DESCRIPTION OF EMBODIMENTS

Hereinafter, a method of manufacturing a photo detector and a photo detector manufactured thereby will be described according to embodiments of the preset invention with reference to the accompanying drawings. Described embodiments below are provided to allow those skilled in the art to understand the scope of the preset invention, but the present invention is not limited thereto. Embodiments of the present invention may be modified in other forms within the technical idea and scope of the present invention. In the specification, ‘and/or’ means that it includes at least one of listed components. These terms are only used to distinguish one element from another element. It will also be understood that when a layer (or film) is referred to as being ‘on’ another layer or substrate, it can be directly on the other layer or substrate, or intervening layers may also be present. It will be understood that although the terms first and second are used herein to describe various elements, these elements should not be limited by these terms. In the figures, the dimensions of layers and regions are exaggerated for clarity of illustration.

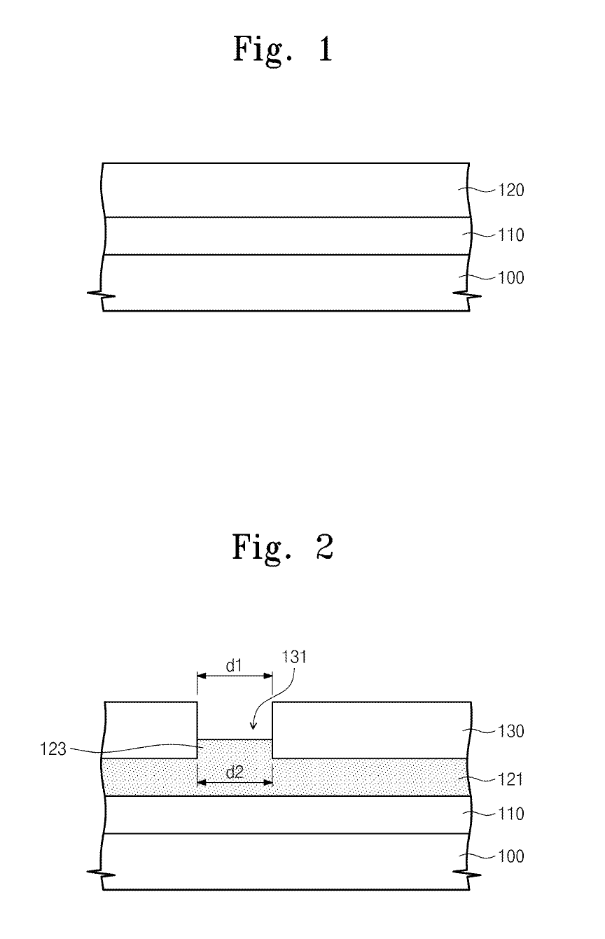

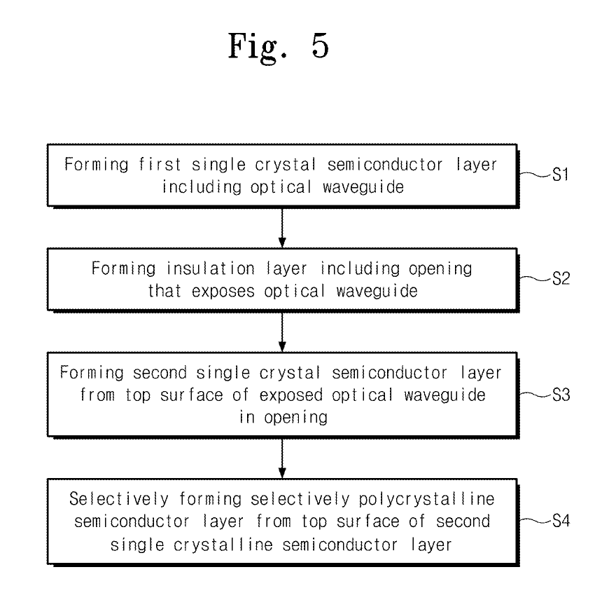

A method of manufacturing a photo detector will be described with reference to FIGS. 1 through 5 according to embodiments of the present invention. FIGS. 1 through 4 are manufacturing sectional views illustrating embodiments of the present invention. FIG. 5 is a flowchart illustrating a manufacturing method according to embodiments of the present invention.

Referring to FIG. 1, a Silicon On Insulator (SOI) substrate may be prepared. The SOI substrate includes a silicon substrate 100, a buried insulation layer 110 on the silicon substrate 100, and a first single crystal semiconductor layer 120 on the buried insulation layer 110.

Referring to FIG. 2, an optical waveguide may be formed by etching the first single crystal semiconductor layer 120 in operation S1. The first single crystal semiconductor layer 120 may be dry-etched. The optical waveguide 123 may be a portion protruding from the etched first single crystal semiconductor layer 121. For example, the top surface of the optical waveguide 123 may be higher than the top surface of the etched first single crystal semiconductor layer 121. Additionally, the optical waveguide 123 may have a sidewall extending from an upper surface of the etched first single crystal semiconductor layer 121.

The optical waveguide 123 and the etched first single crystal semiconductor layer 121 may be doped with first conductive dopants. For example, the optical waveguide 123 and the etched first single crystal semiconductor layer 121 may be doped with p-type dopants. The optical waveguide 123 and the etched first single crystal semiconductor layer 121 may be doped before and/or after the forming of the optical waveguide 123.

A first interlayer insulation layer 130 may be formed on the etched first single crystal semiconductor layer 121. The first interlayer insulation layer 130 may be formed to cover the optical waveguide 123. The top surface of the first interlayer insulation layer 130 may be planarized.

An opening 131 that exposes the top surface of the optical waveguide 123 may be formed by etching the first interlayer insulation layer 130 in operation S2. After an etching mask is formed on the first interlayer insulation layer 130, the opening 131 may be formed by performing a dry etching process that uses the etching mask as a mask. The width d1 of the opening 131 may be substantially identical to or less than the width d2 of the optical waveguide 123. Thereby, the opening 131 may selectively expose the top surface of the optical waveguide 123. Additionally, the sidewall of the optical waveguide 123 may be surrounded by the first interlayer insulation layer 130 and may be not exposed by the opening 131. In one embodiment, the sidewall of the optical waveguide 123 defined by the etched first interlayer insulation layer 130 may be aligned with the sidewall of the first interlayer insulation layer 130 contacting the sidewall of the optical waveguide 123.

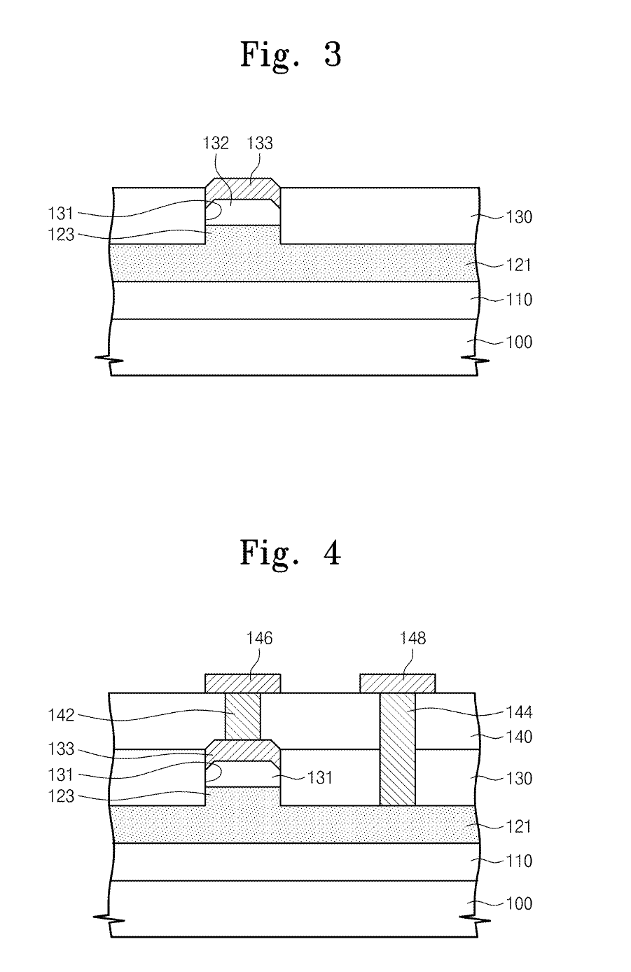

Referring to FIG. 3, a second single crystal semiconductor layer 132 may be formed from the top surface of the optical waveguide 123 in the opening 131 in operation S3. The second single crystal semiconductor layer 132 may be selectively grown from the top surface of the optical waveguide 123. That is, the second single crystal semiconductor layer 132 may not be substantially formed on the sidewall of the first interlayer insulation layer 130 and the top surface of the first interlayer insulation layer 130.

The second single crystal semiconductor layer 132 may be formed through Reduced Pressure Chemical Vapor Deposition (RPCVD) and/or Ultra-High Vacuum Chemical Vapor Deposition (UHVCVD).

The forming of the second crystalline semiconductor layer 132 may include a first formation process performed in a relatively lower temperature and a second formation process performed in a relatively higher temperature than the first formation process.

The first formation process may be performed within a temperature range of about 300° C. to about 500° C. During the first formation process, a pressure in a reaction chamber may be about 30 Torr to about 80 Torr. The first formation process includes providing a first source gas containing germanium into the reaction chamber. In one embodiment, the first formation process includes providing GeH₄ gas into the reaction chamber. The first source gas may be provided into the reaction chamber with a flow rate of about 50 sccm to about 150 sccm. In the first formation process, H₂ gas may be used as a first carrier gas. The first carrier gas may be provided into the reaction chamber with a flow rate of about 10 slm to about 30 slm. The second single crystal semiconductor layer 132 formed by the first formation process may have a thickness of about 100 nm to about 200 nm.

The second formation process is performed following the first formation process. The second formation process may be performed within a temperature range of about 600° C. to about 700° C. The second formation process may be performed at the same pressure condition as the first formation process. For example, during the second formation process, a pressure in a reaction chamber may be about 30 Ton to about 80 Torr. The second formation process includes providing a second source gas containing germanium into the reaction chamber. In one embodiment, the second formation process includes providing GeH₄ gas into the reaction chamber. The second source gas may be provided into the reaction chamber with a flow rate of about 20 sccm to about 50 sccm. In the second formation process, H₂ gas may be used as a second carrier gas. The second carrier gas may be provided into the reaction chamber with a flow rate of about 10 slm to about 30 slm. The second single crystal semiconductor layer 132 formed by the first formation process may be thicker than the second single crystal semiconductor layer 132 formed by the first formation process. For example, the second single crystal semiconductor layer 132 formed by the second formation process may have a thickness of about 500 nm to about 1000 nm.

The first formation process and the second formation process may be successively performed in the same reaction chamber.

A process is performed to form poly semiconductor layer is performed in the reaction chamber on which the second formation process. Accordingly, a poly semiconductor layer 133 may be formed on the second crystalline semiconductor layer 132 in operation S4. The second poly semiconductor layer 133 may be selectively grown from the top surface of the second single crystal semiconductor layer 132.

A process for forming the poly semiconductor layer 133 and the second formation process may be successively performed. That is, the reaction chamber on which the first and second formation processes are performed may be identically used for the forming of the poly semiconductor layer 133. Additionally, a pressure in the reaction chamber during the forming of the poly semiconductor layer 133 may be substantially identical to that of the first and second formation processes. A process for forming the poly semiconductor layer 133 may be performed at a temperature range of about 650° C. and about 750° C.

The forming of the poly semiconductor layer 133 includes providing a poly semiconductor source gas refined with high purity. For example, the poly semiconductor source gas may be at least one of gases including semiconductor elements such as SiH₄ and SiH₂Cl₂. The poly semiconductor source gas may be provided into the reaction chamber with a flow rate of about 100 sccm to about 400 sccm. During the formation process of the poly semiconductor layer 133, H₂ gas may be used as a carrier gas. Additionally, HCI gas may be provided in the reaction chamber to perform the selective growth of the poly semiconductor layer 133. The HCI gas may be provided into the reaction chamber with a flow rate of about 10 scm to about 100 scm.

The poly semiconductor layer 133 may be doped. The poly semiconductor layer 133 may be doped by an in-situ process. In this case, doping gas may be provided in the reaction chamber during the forming of the poly semiconductor layer 133. The doping gas may be selected depending on a conductive type of a dopant in the first single crystal semiconductor layer 121. If the dopants doped in the first single crystal semiconductor layer 121 have a first conductive type, the doping gas may be selected from one of gases for doping of the second conductive type dopants. For example, when the first single crystal semiconductor layer 121 includes p-type dopants, doping gas used for doping of the poly semiconductor layer 133 may be gas including P, (e.g., PH₃). For another example, the first single crystal semiconductor layer 121 includes n-type dopants, doping gas used for doping of the poly semiconductor layer 133 may be gas including B, (e.g., B₂H₆).

Since the second poly semiconductor layer 133 may be selectively grown from the top surface of the second single crystal semiconductor layer 132, a characteristic of a photo detector including an optical waveguide may be improved.

When a poly semiconductor layer doped through an ion implantation of the poly semiconductor layer is formed after the formation and planarization of the poly semiconductor layer on the optical waveguide, defects may occur in the second single crystal semiconductor layer adjacent to the poly semiconductor layer during the ion implantation. Additionally, the thickness of the poly semiconductor layer may not be adjusted easily due to ion implantation, such that there is limitation in increasing quantum efficiency. In another method, for example, after the forming of the single crystal semiconductor layer doped on the second single crystal semiconductor layer 132, when the poly semiconductor layer is formed by patterning the doped single crystal semiconductor layer, manufacturing cost can be increased by the patterning process.

However, if the poly semiconductor layer 133 is selectively formed according to embodiments of the present invention, defect occurrence may be minimized in the second single crystal semiconductor layer 132 during the forming of the poly semiconductor layer 133. Additionally, according to the formation method of the photo detector according to embodiments of the present invention, the thickness of the poly semiconductor layer 133 may be easily adjusted such that a photo detector having improved quantum efficiency may be formed. Furthermore, when the poly semiconductor layer 133 is selectively grown on the second single crystal semiconductor layer 132 according to embodiments of the present invention, it is not necessary to perform a photolithography process and an etching process for patterning such that manufacturing cost may be reduced. Accordingly, manufacturing efficiency may be improved.

Referring to FIG. 4, a second interlayer insulation layer 140 may be formed on the first interlayer insulation layer 130. Contact holes may be formed to expose the top surface of the poly semiconductor layer 133 and the top surface of the first single crystal semiconductor layer 121 by etching the second interlayer insulation layer 140. First and second contacts 142 and 144 may be formed by filling the contact holes with a conductive material. The first and second contacts 142 and 144 may include at least one selected from various conductive materials including a doped semiconductor, metal, and a metal compound.

Before filling the first and second contacts 142 and 144 with the conductive material, a process is further performed to metalize the top surface of the poly semiconductor layer 133 and the top surface of the first single crystal semiconductor layer 121. When the poly semiconductor layer 133 includes poly silicon, the metalizing process may be a silicidizing process. The silicidizing process is a process for performing a thermal treatment process after a metal layer is deposited in the contact holes. Conductive patterns 146 and 148 may be formed on the contact holes 142 and 144. The conductive patterns 146 and 148 may be an island type or a line type.

Referring to FIG. 4, a photo detector is described according to one embodiment of the present invention. The previously described contents may be omitted.

Referring to FIG. 4, the buried oxide 110 may be disposed on the substrate 100 and the first single crystal semiconductor layer 121 may be disposed on the buried oxide 110. The optical waveguide 123 may be disposed on the first single crystal semiconductor layer 121. The optical waveguide 123 may change into various forms according to an applied device of a ring type and a line type. The optical waveguide 123 may have sidewalls extending upwardly from the top surface of the first single crystal semiconductor layer 121 and have the top surface disposed higher than the top surface of the first single crystal semiconductor layer 121. The optical waveguide 123 may include a single crystal semiconductor. For example, the optical waveguide 123 may be a portion of the first single crystal semiconductor layer 121. That is, the optical waveguide 123 may include the same semiconductor material as the first single crystal semiconductor layer 121. In one embodiment, the optical waveguide 123 may be formed by etching a portion of the first single crystal semiconductor layer 121. The optical waveguide 123 and the etched first single crystal semiconductor layer 121 may be doped with first conductive dopants.

The first interlayer insulation layer 130 is formed on the first single crystal semiconductor layer 121. The first interlayer insulation layer 130 may include an opening 131 that exposes the top surface of the optical waveguide 123. The optical waveguide 123 may fill a lower portion of the opening 131. The width of the opening 131 may be substantially identical to the width of the optical waveguide 123. In one embodiment, the sidewall of the opening 131 may be self-aligned with the sidewall of the optical waveguide 123.

A second single crystal semiconductor layer 132 is disposed in the opening 131. The second single crystal semiconductor layer 132 may have a lower top surface than the first interlayer insulation layer 130. For example, the second single crystal semiconductor layer 132 may have the edge portion of the top surface lower than the top surface of the adjacent first interlayer insulation layer 130. In addition, the second single crystal semiconductor layer 132 may have the middle of the top surface lower than the top surface of the adjacent first interlayer insulation layer 130. In one embodiment, the top surface of the second single crystal semiconductor layer 132 may not be planarized. That is, the second single crystal semiconductor layer 132 may have the relatively higher top surface at the middle portion and may have a relatively lower top surface at the edge portion.

The second single crystal semiconductor layer 132 may include different semiconductor elements from the first single crystal semiconductor layer 121 and the optical waveguide 123. For example, the first single crystal semiconductor layer 121 and the optical waveguide 123 include single crystal silicon, and the second single crystal semiconductor layer 132 may include single crystal germanium. For another example, the first single crystal semiconductor layer 121 and the optical waveguide 123 include single crystal silicon, and the second single crystal semiconductor layer 132 may include single crystal silicon-germanium. The second single crystal semiconductor layer 132 may be a genuine semiconductor layer that is not doped with dopants. The second intricsic single crystal semiconductor layer 132 may have a thickness of about 600 nm to about 1200 nm.

A poly semiconductor layer 133 may be formed on the second single crystal semiconductor layer 132. At least a portion of the poly semiconductor layer 133 may fill the opening 131. For example, the edge portion of the poly semiconductor layer 133 may be disposed in the opening 131. The poly semiconductor layer 133 may have the top surface at the middle portion that is higher than the top surface at the edge portion. The poly semiconductor layer 133 may have the top surface at the middle portion that is higher than the top surface of the first interlayer insulation layer 130. Alternatively, the poly semiconductor layer 133 may have the top surface at the middle portion that is substantially identical to or lower than the top surface of the first interlayer insulation layer 130. The poly semiconductor layer 133 may have a profile of the top surface that is substantially identical to that of the second single crystal semiconductor layer 132. The poly semiconductor layer 133 may include a semiconductor in a polycrystalline state. For example, the poly semiconductor layer 133 may include poly silicon.

A first contact 142 may be disposed on the poly semiconductor layer 133. The first contact 142 may penetrate the second interlayer insulation layer 140 on the first interlayer insulation layer 130. A metal-semiconductor compound layer may be interposed between the poly semiconductor layer 133 and the first contact 142. The metal-semiconductor compound layer may include metal silicide, for example. The first conductive pattern 146 may be disposed on the first contact 142. The conductive pattern 146 may have an island type or a line type.

The second contact 144 may be disposed to penetrate the second interlayer insulation layer 140 and the first interlayer insulation layer 130 on the first single crystal semiconductor layer 121. The second contact 144 may be electrically connected to the first single crystal semiconductor layer 121. A metal-semiconductor compound layer may be disposed between the second contact 144 and the first single crystal semiconductor layer 121. A metal-semiconductor compound layer (e.g., metal silicide) may be disposed between the second contact 144 and the first single crystal semiconductor layer 121. The second conductive pattern 148 may be disposed on the second contact 144. The second conductive pattern 148 may have an island type or a line type.

According to embodiments of the present invention, a poly semiconductor layer may be selectively grown from a single crystal semiconductor layer. Accordingly, processes for forming the poly semiconductor layer can be simplified. Additionally, device defects that can occur during the forming of the poly semiconductor layer may be reduced due to simplified processes.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A manufacturing method of a photo detector, the method comprising:
forming a first single crystal semiconductor layer and an optical waveguide protruding from the first single crystal semiconductor layer;
forming an insulation layer on the first single crystal semiconductor layer to cover the optical waveguide;
forming an opening by etching the insulation layer to expose the top surface of the optical waveguide;
forming a second single crystal semiconductor layer from the top surface of the exposed optical waveguide, in the opening; and
selectively forming a poly semiconductor layer from the top surface of the second single crystal semiconductor layer, the poly semiconductor layer being doped with dopants.

2. The method of claim 1, wherein the forming of the second single crystal semiconductor layer and the forming of the poly semiconductor layer are successively performed in the same reaction chamber.

3. The method of claim 1, further comprising doping the first single crystal semiconductor layer with dopants of a first conductive type, wherein the doping of the dopants of the first conductive type is accomplished before the forming of the second single crystal semiconductor layer.

4. The method of claim 3, wherein:
the poly semiconductor layer is doped with dopants of a second conductive type opposite to the first conductive type; and
the dopants of the second conductive type are doped in the poly semiconductor layer by an in-situ process.

5. The method of claim 1, wherein the first single crystal semiconductor layer comprises silicon single crystal and the second single crystal semiconductor layer comprises single crystal germanium or single crystalline silicon-germanium.

6. The method of claim 1, wherein the forming of the first single crystal semiconductor layer comprises performing a dry etching process on a silicon layer of a Silicon On Insulator (SOI) substrate.

7. The method of claim 1, wherein the second single crystal semiconductor layer and the poly semiconductor layer are formed through Reduced Pressure Chemical Vapor Deposition (RPCVD) or Ultra-High Vacuum Chemical Vapor Deposition (UHVCVD).

8. The method of claim 1, wherein the forming of the second single crystal semiconductor layer comprises a first step performed at a first temperature and a second step performed at a second temperature after the first step is performed, the second temperature being different from the first temperature and higher than the first temperature.

9. The method of claim 8, wherein:
the first step comprises providing GeH₄ gas at a temperature of about 300° C. to about 500° C. and a pressure of about 30 Torr to about 80 Torr; and
the second step comprises providing GeH₄ gas at a temperature of about 600° C. to about 700° C. and a pressure of about 30 Torr to about 80 Torr.

10. The method of claim 1, wherein the forming of the poly semiconductor layer comprises providing at least one of SiH₄ and GeH₄ and a carrier gas and is performed at a temperature of about 650° C. to about 750° C. and a pressure of about 30 Torr to about 80 Torr.

11. The method of claim 10, wherein the forming of the poly semiconductor layer further comprises providing HCI gas.

12. The method of claim 1, wherein the opening has a width that is identical to or narrower than the width of the optical waveguide.

13. The method of claim 1, wherein the forming of the opening comprises performing a dry etching process.

14. A photo detector comprises:
a substrate;
a buried oxide layer and a first single crystal semiconductor layer stacked on the substrate sequentially;
an optical waveguide protruding from the first single crystal semiconductor layer;
a second single crystal semiconductor layer having a sidewall that is self-aligned with a sidewall of the optical waveguide; and
a poly semiconductor layer having a sidewall that is self-aligned with the sidewalls of the optical waveguide and the second single crystal semiconductor layer,
wherein the optical waveguide comprises a portion protruding from the first single crystal semiconductor layer and the top surface of the second single crystal semiconductor layer is non-planarized.

15. The photo detector of claim 14, wherein the top surface of the poly semiconductor layer has the same profile as the second single crystal semiconductor layer.

16. The photo detector of claim 14, further comprising:
a first interlayer insulation layer on the first single crystal semiconductor layer to surround the sidewalls of the optical waveguide, wherein an edge portion of the top surface of the optical waveguide is disposed lower than the top surface of the first interlayer insulation layer.

17. The photo detector of claim 16, wherein at least a portion of the top surface of the poly semiconductor layer is disposed higher than the top surface of the first interlayer insulation layer.

18. The photo detector of claim 16, further comprising:
a second interlayer insulation layer on the first interlayer insulation layer;
a first electrode contact connected to the poly semiconductor layer electrically and penetrating the second interlayer insulation layer; and
a second electrode contact connected to the first single crystal semiconductor layer electrically and penetrating the first interlayer insulation layer and the second interlayer insulation layer.

19. The photo detector of claim 18, further comprising a silicide layer between the poly semiconductor layer and the second electrode contact, wherein the poly semiconductor layer comprises poly silicon.

20. The photo detector of claim 14, wherein:
the first single crystal semiconductor layer is doped with dopants of a first conductive type;
the poly semiconductor layer is doped with dopants of a second conductive type opposite to the first conductive type; and
the second single crystal semiconductor layer is intrinsic semiconductor.
